(19) United States
(12) Patent Application Publication
(10) Pub. No.: US 2022/0407000 A1
(43) Pub. Date: Dec. 22, 2022

(54) MEMORY WITH LAMINATED CELL

(71) Applicants: MACRONIX INTERNATIONAL CO., LTD., Hsinchu (TW); INTERNATIONAL BUSINESS MACHINES CORPORATION, Armonk, NY (US)

(72) Inventors: Chih-Hsiang YANG, New Taipei City (TW); Hsiang-Lan LUNG, ARDSLEY, NY (US); Wei-Chih CHIEN, Taipei (TW); Cheng-Wei CHENG, Yorktown Heights, NY (US); Matthew J. BRIGHTSKY, Armonk, NY (US)

(73) Assignees: MACRONIX INTERNATIONAL CO., LTD., Hsinchu (TW); INTERNATIONAL BUSINESS MACHINES CORPORATION, Armonk, NY (US)

(21) Appl. No.: 17/349,359

(22) Filed: Jun. 16, 2021

(51) Int. Cl. H01L 45/00; H01L 27/24

(52) U.S. Cl. CPC H01L 45/1293; H01L 27/2427; H01L 27/2481; H01L 45/06; C23C 16/345

(57) ABSTRACT

A memory cell formed in a pillar structure between a first electrode and a second electrode includes laminated encapsulation structure. In one example, the pillar includes a body of ovonic threshold switch material, carbon-based intermediate layers, metal layers and a body of phase change memory material in electrical series between the first and second electrodes. The laminated encapsulation structure surrounds the pillar. The laminated dielectric encapsulation structure comprises at least three conformal layers, including a first layer of material, a second conformal layer of a second layer material different from the first layer material; and a third conformal layer of a third layer material different from the second layer material.

International Business Machines Corporation, a New York corporation, and Macronix International Corporation, Ltd., a Taiwan corporation, are parties to a Joint Research Agreement.

### BACKGROUND

### Technical Field

The technology described herein relates to integrated circuit memory technologies, including technologies using programmable resistance memory materials, including phase change materials, in 3D cross-point architectures, and methods for manufacturing such devices.

### Description of Related Art

Three dimensional (3D) memory technologies using phase change material, and other programmable resistance materials have been proposed in order to improve data storage density and reduce costs. For example, Lung, U.S. Pat. No. 6,579,760 entitled SELF-ALIGNED, PROGRAMMABLE PHASE CHANGE MEMORY, issued Jun. 17, 2003.

Phase change materials, like chalcogenide-based materials and similar materials, can be caused to change phase by application of electrical current at levels suitable for implementation in integrated circuits. The generally amorphous state in a phase change material is usually characterized by higher resistivity than the generally crystalline state, and the difference in resistivity can be readily sensed to indicate data.

The change from the amorphous to the crystalline phase is generally a lower current operation. The change from crystalline to amorphous, referred to as reset herein, is generally a higher current operation, which can include a short high current density pulse to melt or breakdown the crystalline structure, after which the phase change material cools quickly, quenching the phase change process and allowing at least a portion of the phase change structure to stabilize in the amorphous phase.

It is desirable to minimize the magnitude of the reset current used to cause the transition of the phase change material from a crystalline state to an amorphous phase. In order to more efficiently heat an active region of the phase change material to cause phase changes, techniques have been used to thermally isolate the active region in the phase change cell. Thermal isolation tends to confine the resistive heating needed to induce the phase change is confined to the active region; and tends to reduce thermal cycling of the surrounding materials. Thus, thermal isolation can contribute to reduction of power required and increasing speeds of operation. Also, thermal isolation may improve the endurance of the memory cells in the memory.

It is desirable to provide a memory structure that is readily manufacturable for high density structures, can operate with high speed and low power, and has good endurance.

### SUMMARY

A memory cell technology is described that includes laminated encapsulation structure for thermal isolation. An embodiment described includes a first electrode and a second electrode; a stack of materials having a side wall in electrical series between the first and second electrodes, and including a layer of programmable resistance memory material. A laminated encapsulation structure surrounds the stack. The laminated encapsulation structure comprises a first conformal layer of a first material which can be formed by atomic layer deposition (ALD) on the side wall of the stack, a second conformal layer of a second material which can be formed by atomic layer deposition (ALD) different from the first material in contact with the first conformal layer; and a third conformal layer of a third material which can be formed by atomic layer deposition (ALD), different from the second material in contact with the second conformal layer. The first conformal layer can act as a protective layer during formation of subsequent layers of the laminated encapsulation, and is a means for protecting the stack of materials forming memory cells from processes used to form the second conformal layer. In some embodiments, the first conformal layer is silicon nitride, or another compound that as deposited, does not include oxygen. In some embodiments, the first conformal layer is a compound deposited by ALD. In some embodiments, the first conformal layer is substantially thicker than each of the second and third conformal layers, which because of its substantial thickness can protect the memory cell stack. A conformal layer as the term is used herein, is a layer which conforms to the contours of the underlying layer on which it is formed, and in some embodiments can have a substantially uniform thickness across most of its area, so that the contours of the underlying layer are largely preserved on the surface of the conformal layer.

A memory cell is described having a pillar structure between a first electrode and a second electrode. In one example, the pillar includes a body of ovonic threshold switch material, one of more carbon-based intermediate layers, and a body of phase change memory material in electrical series between the first and second electrodes. In some embodiments, a side wall spacer or side wall dielectric layer can be disposed in the pillar on the sides of the body of phase change material. A laminated encapsulation structure surrounds the pillar. The laminated encapsulation structure comprises a first conformal layer of a first layer material adjacent the phase change memory material (or the side wall spacer or side wall dielectric), a second conformal layer of a second layer material different from the first layer material in contact with the first conformal layer; and a third conformal layer of a third layer material different from the second layer material in contact with the second conformal layer. The laminated encapsulation structure comprises, in these embodiments, a first conformal layer of silicon nitride (or other non-oxygen containing material) on a side wall of the pillar, a second conformal layer of a second layer material different from the material of the first conformal layer in contact with the first conformal layer, and a third conformal layer in contact with the second conformal layer. Examples of material for the second conformal layer can be silicon oxide, aluminum oxide, silicon carbide, siliconoxynitride and so on. Examples of material for the third conformal layer can be silicon nitride, silicon oxide, aluminum oxide, silicon carbide, siliconoxynitride and so on. The first conformal layer can be thicker than the second and third conformal layers.

Embodiments are described in which the memory cells include a layer of ovonic threshold switch material, one or more carbon-based layers and a body of phase change memory material in electrical series. The laminated encapsulation structure comprises, in these embodiments, a first conformal layer of silicon nitride on a side wall of the memory cells, a second conformal layer of a second layer material of silicon oxide in contact with the first conformal layer, and a third conformal layer of silicon nitride in contact with the second conformal layer.

An integrated circuit memory and a memory structure are described including a layer of first conductors extending in a first direction alternating with a layer of second conductors extending in a second direction, and an array of memory cells disposed in cross-points between first conductors and second conductors. Each memory cell in a corresponding cross-point in the array comprises a layer of ovonic threshold switch material, one of more carbon-based layers and a body of phase change memory material in electrical series. Laminated encapsulation is used, as described above.

Other aspects and advantages of the present invention can be seen on review of the drawings, the detailed description and the claims, which follow.

### BRIEF DESCRIPTION OF THE DRAWINGS

FIG. 1 is a simplified cross-section of a pillar-type memory cell which includes a selector element and a phase change memory element in series, and has laminated thermal isolation encapsulation as described herein.

FIG. 2 is a simplified cross-section of another embodiment of a pillar-type memory cell, in which the phase change memory element is further confined by side wall spacers, and has laminated thermal isolation encapsulation as described herein.

FIG. 3 is a simplified cross-section of yet another embodiment of a pillar-type memory cell, including native oxide liners on the phase change memory element and selector element materials.

FIG. 4 is a diagram showing a structure of a laminated thermal isolation encapsulation structure according to one embodiment.

FIG. 5 is a diagram showing a structure of a laminated thermal isolation encapsulation structure according to another embodiment.

FIG. 6 is a perspective view of another pillar-type memory cell embodiment having a laminated thermal isolation encapsulation structure.

FIG. 7 illustrates a procedure for atomic layer deposition of a layer of silicon nitride suitable for use in forming laminated thermal isolation encapsulation structures as described herein.

FIG. 8 illustrates a procedure for atomic layer deposition of a layer of silicon oxide suitable for use in forming laminated thermal isolation encapsulation structures as described herein.

FIG. 9 is a simplified illustration of one layer of a three-dimensional cross-point memory array, in which memory cells as described herein are deployed.

FIG. 10 is a simplified block diagram of an integrated circuit with a 3D memory array with thermally isolated, laminated memory cells, as described herein.

### DETAILED DESCRIPTION

A detailed description of embodiments of the present invention is provided with reference to the FIGS. 1-10.

FIG. 1 illustrates a memory cell comprising a pillar of materials arranged between a first conductor 111 and a second conductor 112. The pillar comprises a stack of materials having a side wall, such as a cylindrical side wall or prismatic side wall, and includes a layer of programmable resistance memory material. The first conductor 111 can be configured as a word line for connection to decoded voltage drivers, and the second conductor 112 can be configured as a bit line for connection to sense amplifiers. The pillar forms a memory cell including a memory element and a switch element disposed between first conductor 111 and second conductor 112. In this example, the pillar includes in series between the first conductor 111 and the second conductor 112, a first intermediate layer 117, a phase change memory material layer 116 which acts as a memory element, a second intermediate layer 115, an ovonic threshold switch OTS material layer 114 which acts as a switch element, and a third intermediate layer 113. The intermediate layers can act as barrier layers between materials. The intermediate layers can act as adhesion layers between materials. The intermediate layers can act as heater layers between materials. The pillar materials are configured so that the memory element and the switch element are in electrical series between the first conductor 111 and the second conductor 112.

In another example, the switch element and memory element are inverted, so that the memory element is closer to the second conductor 112.

The laminated encapsulation structure 120 comprises a plurality of superposed layers of different materials. In advantageous embodiments, all of the superposed layers in the laminated encapsulation structure 120 are atomic layer deposition (ALD) materials formed by sequential ALD processes that include sequential, self-limiting reactions. In some embodiments, one or more of the superposed layers in the laminated encapsulation structure 120 are ALD materials formed by ALD. ALD offers exceptional conformality on high-aspect ratio structures, thickness control at the Angstrom level, and tunable film composition. The superposed layers of the ALD encapsulation structure include a first layer on the side wall of the pillar. In examples described herein, the first layer is material selected because it does not include oxygen, or because the self-limiting reaction used to form the first layer does not include an oxygen source such as oxygen plasma or ozone, which might undesirably react with materials of the pillar. In one example, the first layer of the ALD encapsulation structure comprises silicon nitride. More details of laminated encapsulation structure structures are described below.

Although not illustrated, the pillar is surrounded by the suitable dielectric material, such as a suitable interlayer dielectric or dielectric fill material used in the manufacturing of the memory device in which the memory cells are deployed.

The phase change material layer 116 can comprise chalcogenide-based materials, for example Ge₁SbₓTe₁ (x is from 1 to 6) with doped silicon oxide or silicon nitride; Ge₂Sb₂Te_{y} (y is 5 or 6) doped with silicon oxide or silicon nitride; Ge₂Sb_{z}Te₅ (z is 3 or 4) doped with silicon oxide or silicon nitride. Other example materials include a variety of stoichiometries of gallium Ga, antimony Sb and tellurium Te, doped with silicon oxide or silicon nitride.

In some embodiments, the memory material layer can comprise a programmable resistance material like a metal oxide used for ReRAM, a magnetic material as used in MRAM, or a ferro-electric material as used in FeRAM.

The layer 114 forming the switching element can comprise a chalcogenide combination selected for operation as an ovonic threshold switch OTS. For example, the OTS material used as a switch element can be a compound including As, Se and Ge, and can be doped one or more elements selected from a group including In, Si, S, B, C, N, and Te. Example OTS switch materials can include one or more elements selected from the group comprising arsenic (As), tellurium (Te), antimony (Sb), selenium (Se), germanium (Ge), silicon (Si), oxygen (O) and nitrogen (N). In one example, switching layer 114 can have a thickness of about 10 nm to about 40 nm, preferably about 30 nm. Czubatyj et al., “Thin-Film Ovonic Threshold Switch: Its Operation and Application in Modern Integrated Circuits,” Electronic Materials Letters, Vol. 8, No. 2 (2012), pages 157-167, describes applications and electrical characteristics of the thin-film Ovonic Threshold Switch (OTS).

In other embodiments, other current steering devices can be utilized, including diodes, transistors, tunneling dielectric layers, and so on.

Intermediate layers 113, 115, 117 can all have the same composition in some embodiments. In other embodiments, they can have different compositions selected according to the materials which contact them on either side. For example, the intermediate layer 115 can comprise a material or combination of materials selected to provide adequate adhesion to the layer 114 and the layer 116, and to block movement of impurities from one layer of the pillar into materials in the adjacent layers. The intermediate layers 113, 115, 117 can be comprised of conductive material with a thickness of about 3 to about 30 nm, preferably about 10 nm, forming a conductive intermediate layer. Appropriate barrier materials include metals such as tungsten W, metal nitrides, for example, titanium nitride (TiN), tantalum nitride (TaN), tungsten nitride (WN), molybdenum nitride (MoN), titanium silicon nitride (TiSiN), titanium aluminum nitride (TiAlN). In addition to metal nitrides, conductive materials, such as titanium carbide (TiC), silicon carbide (SiC), tungsten carbide (WC), forms of carbon such as graphite (C), titanium (Ti), molybdenum (Mo), tantalum (Ta), titanium silicide (TiSi), platinum silicide (PtSi) tantalum silicide (TaSi), and titanium tungsten (TiW), which can be used for intermediate layers. In some embodiments, a carbon-based barrier material can be used in one or more of the intermediate layers 117, 115, 113. A carbon-based barrier material can include essentially pure carbon, or carbon, doped with silicon or other materials. Carbon-based barrier materials, and other barrier materials, can be damaged by exposure to oxygen sources such as oxygen plasma or ozone utilized as reactants in ALD of some types of materials including, in particular, oxygen containing materials.

The materials chosen for first conductor 111 and second conductor 112 can comprise a variety of metals, metal-like materials and doped semiconductors, and combinations thereof. First conductor 111 and second conductor 112 can be implemented using one or more layers of materials like tungsten (W), aluminum (Al), copper (Cu), titanium nitride (TiN), tantalum nitride(TaN), tungsten nitride (WN), doped polysilicon, cobalt silicide (CoSi), Tungsten silicide (WSi) and other materials. In one example, the conductors 111 and 112 comprise a tri-layer structure including TIN, W and TiN.

In the embodiment of FIG. 1, the first conductor 111 has a width W1 that is defined by a patterning technology, such as photolithography so that it is as small as practical given the manufacturing technologies and operational characteristics. Likewise, the second conductor 112 has a width W2 that is defined by a patterning technology so that it is as small as practical. At the cross-point of the first conductor 111 and the second conductor 112, a cross-point area is defined. A memory cell pillar is disposed within a cylindrical region at the cross-point between the first and second conductors 111, 112, the cross-section of which is defined by the cross-point area (W1×W2) and the etching processes aligned by the sides of the first and second conductors.

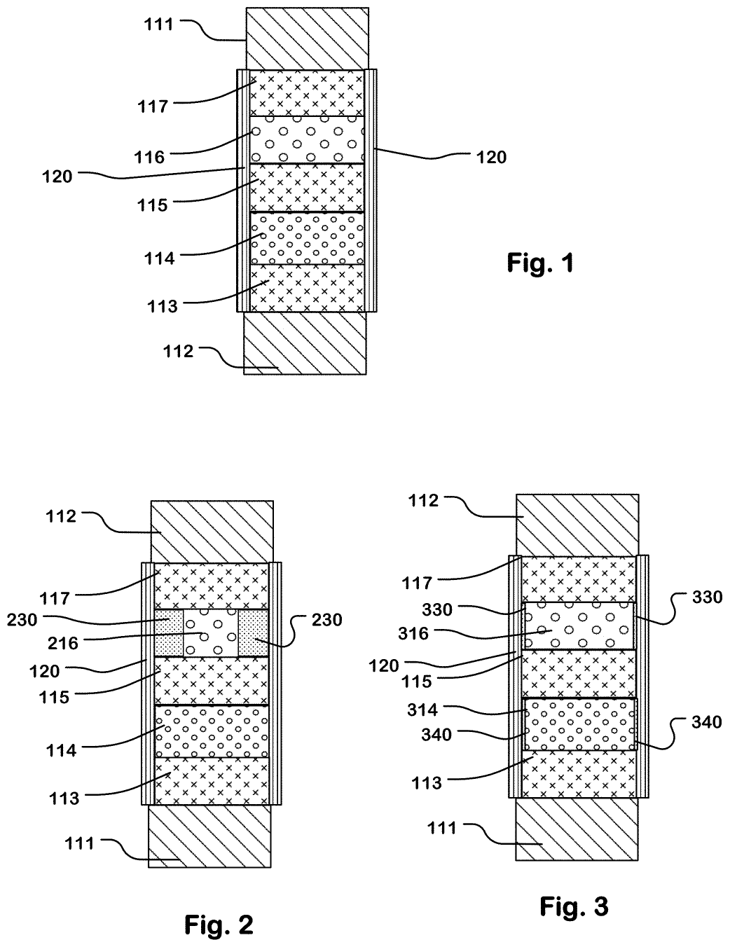

FIG. 2 illustrates an alternative embodiment, in which reference numerals used for like elements in FIG. 1 are not changed. In this example, the pillar is modified in the layer forming the memory element. The memory element includes a layer of phase change material 216 having a side wall spacer 230 which act as a confinement liner that surrounds one or more sides of the phase change material 216. In some embodiments, the side wall spacer 230 completely surrounds the phase change material 216.

The side wall spacer 230 is disposed between the phase change material 216, and the laminated encapsulation structure 120. The side wall spacer 230 can for example comprise a conductor or a resistive material. In some embodiments, the side wall spacer 230 can comprise a surfactant spacer. Some materials that can have sufficient resistivity for use as surfactant spacers include tungsten nitride (WN), molybdenum nitride (MoN), titanium silicon nitride (TiSiN), titanium aluminum nitride (TiAlN). In addition to metal nitrides, conductive materials, such as titanium carbide (TiC), tungsten carbide (WC), graphite (C), other carbon (C) forms, titanium silicide (TiSix,), cobalt silicide CoSix, nickel silicide NiSix, tantalum silicide (TaSix), platinum silicide PtSix, tungsten silicide WSix, and titanium tungsten (TiW), may be used.

In some embodiments, the side wall spacer 230 comprises a dielectric material, such as silicon nitride or silicon oxide.

In the illustrated example, the laminated encapsulation structure 120 contacts the side wall spacer 230, as well as the barrier materials of layers 113, 115, 117. Also, in the illustrated example, the laminated encapsulation structure contacts the OTS material in layer 114.

FIG. 3 illustrates yet another embodiment, in which reference numerals used for like elements in FIG. 1 are not changed. In this example, the pillars are modified by formation of native oxide 330 on the side walls of the layer 316 of memory material, and native oxide 340 on the side walls of the layer 314 of the switch material. The native oxide 330, 340 can comprise oxides of an element of the phase change material, such as a germanium oxide, or an element of the OTS material. Also, the native oxide 330, 340 can comprise a silicon oxide in embodiments in which silicon is included in the memory or switching layers.

In the embodiments illustrated in FIGS. 1-3, a laminated encapsulation structure 120 surrounds the pillar encapsulating the pillar along its entire length between the first conductor 111 and the second conductor 112. In other embodiments, the encapsulation structure 120 may be limited to only the phase change memory material layer 116, or only to a subset of the layers of the pillar. In some embodiments, the subset of the layers of pillars encapsulated by the laminated encapsulation structure 120 includes at least the phase change memory material layer 116 (or other layer forming the memory element) and at least one of intermediate layer 117 and intermediate layer 115. In another embodiment, the subset of layers of pillars encapsulated by the laminated encapsulation structure 120 includes at least the phase change memory material layer 116 (or other layer forming the memory element) and the OTS material in layer 114 (or other layer forming the switch element).

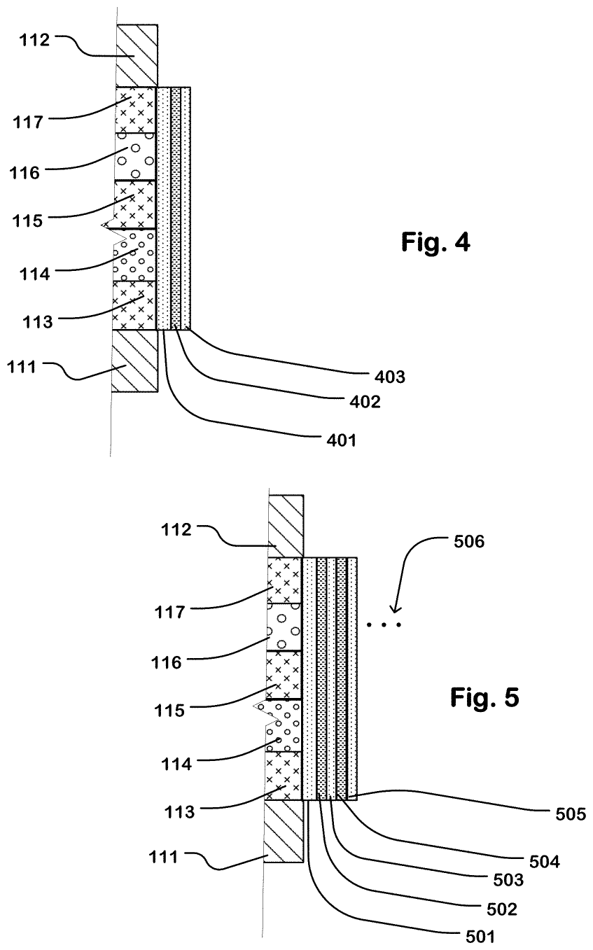

FIG. 4 illustrates a structure of a laminated encapsulation structure, such as the encapsulation structure 120 of FIGS. 1-3. In this example, the laminated encapsulation structure includes a first conformal layer 401 of a first material on the side wall of the stack, a second conformal layer 402 of a second material different from the first material in contact with the first conformal layer, and a third conformal layer 403 of a third material different from the second material in contact with the second conformal layer. The first, second and third conformal layers can be ALD deposited materials.

The first conformal layer 401 includes silicon nitride having a thickness in the range of 5 to 10 nm. The second conformal layer 402 includes a silicon oxide, having a thickness in the range of 2 to 5 nm. The third conformal layer 403 includes a silicon nitride having a thickness in the range of 2 to 5 nm.

FIG. 5 illustrates an alternative structure of a laminated encapsulation structure, such as the encapsulation structure 120 of FIGS. 1-3. In this example, the laminated encapsulation structure includes a first conformal layer 501 on the side walls of the pillar, a second conformal layer 502 on the first conformal layer 501, a third conformal layer 503 on the second conformal layer 502, a fourth conformal layer 504 on the third conformal layer 503, and a fifth conformal layer 505 on the fourth conformal layer 504. The first conformal layer 501 includes ALD deposited silicon nitride having a thickness in the range of 5 to 10 nm. The second conformal layer 502 includes a silicon oxide, having a thickness in the range of 2 to 5 nm. The third conformal layer 503 includes a silicon nitride having a thickness in the range of 2 to 5 nm. The fourth conformal layer 504 includes a silicon oxide, having a thickness in the range of 2 to 5 nm. The fifth conformal layer 505 includes a silicon nitride having a thickness in the range of 2 to 5 nm. The first, second, third, fourth and fifth conformal layers can be ALD deposited materials.

In some embodiments, the alternating conformal layers of the laminated encapsulation structure can include more than five layers, as indicted by the ellipsis 506 in FIG. 5.

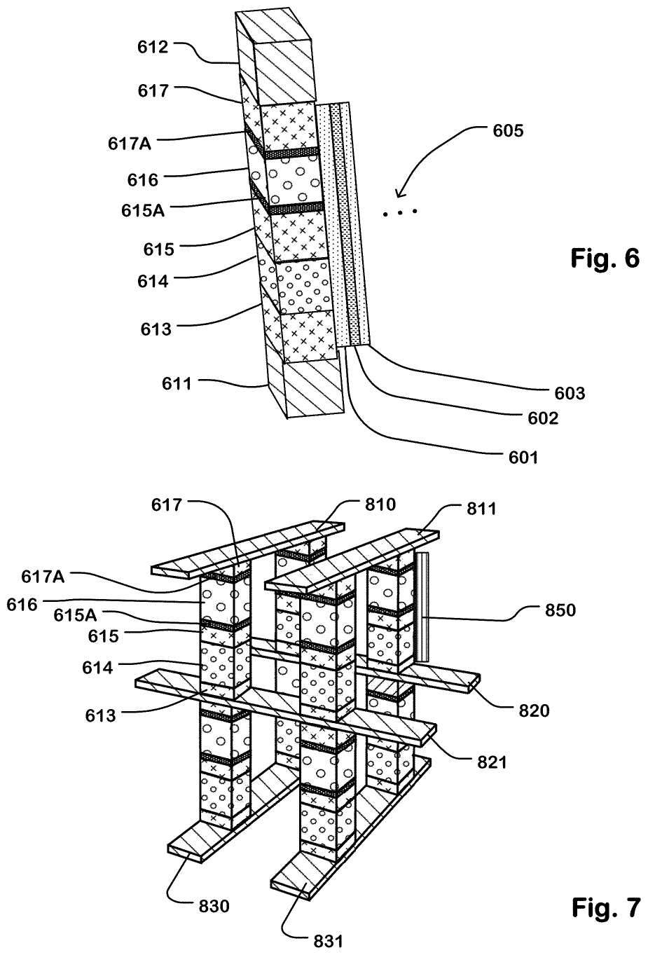

FIG. 6 illustrates a memory cell comprising a pillar of materials arranged between a first conductor 611 and a second conductor 612. The pillar comprises a stack of materials having a side wall, such as a circular, oval or rectangular, cylindrical side wall, and includes a layer of phase change material or other programmable resistance memory material. The first conductor 611 can be configured as a word line for connection to decoded voltage drivers, and the second conductor 612 can be configured as a bit line for connection to sense amplifiers. The pillar forms a memory cell including a memory element and a switch element disposed between first conductor 611 and second conductor 612. In this example, the pillar includes in series between the first conductor 611 and the second conductor 612, a first intermediate layer 613, an ovonic threshold switch OTS material layer 614 which acts as a switch element, a second intermediate layer 615, a phase change memory material layer 616 which acts as a memory element, and a third intermediate layer 617. In this embodiment, the pillar includes layer 615A between the second intermediate layer 615 and the phase change memory material layer 616. In this embodiment, the pillar includes layer 617A between the third intermediate layer 617 and the phase change memory material layer 616. The layers 615A and 617A can comprise a metal such as tungsten or other metal or metal alloy having a melting point above 2000° C. (i.e., refractory metal), or other material chosen for compatibility with the phase change memory material layer 616. The layers 615 and 617 can be carbon-based material or carbon which is pure as deposited. The pillar materials are configured so that the memory element and the switch element are in electrical series between the first conductor 611 and the second conductor 612.

In another example, the switch element and memory element are inverted, so that the memory element is closer to the first conductor 611.

A laminated encapsulation structure is disposed on the side wall and surrounds at least a majority of the perimeter of the pillar. The laminated encapsulation structure includes a first conformal layer 601 of a first material on the side wall of the stack, a second conformal layer 602 of a second material different from the first material in contact with the first conformal layer, and a third conformal layer 603 of a third material different from the second material in contact with the second conformal layer.

The first conformal layer 601 includes silicon nitride having a thickness in the range of 5 to 10 nm. The second conformal layer 602 includes silicon oxide, having a thickness in the range of 2 to 5 nm. The third conformal layer 603 includes silicon nitride having a thickness in the range of 2 to 5 nm. More than three layers can be used in some embodiments as indicated by the ellipsis 605.

In the desirable embodiments, the materials in the alternating layers of the laminated encapsulation structure comprise silicon nitride and silicon oxide. In other embodiments, different materials can be utilized including for example aluminum oxide, silicon carbide, siliconoxynitride and so on. It is desirable that the materials used in the alternating layers have distinct atomic structures causing lattice mismatches or irregularities, so that interfaces between them are resistant to thermal conduction. As mentioned above, the first conformal layer of the laminated encapsulation structure is selected so that its deposition does not include reactant materials which can damage materials used in the pillar, such as the materials of the intermediate layers. In embodiments described herein, the first conformal layer (401, 501, 601) does not include oxygen. Alternatively, the first conformal layer (401, 501, 601) is a material that is deposited without use of oxygen-carrying reactants such as oxygen plasma or ozone. Also, in embodiments described herein, the first conformal layer (401, 501, 601) has a thickness of about 5 to 10 nm, or more in some cases, so that it acts as a protective layer during ALD deposition of subsequent layers of the laminated encapsulation structure. Also, the first conformal layer can be thicker than each of the overlying conformal layers.

It is found that more than two conformal layers in the laminated encapsulation structure can result in a substantial improvement in operating characteristics of the memory cell. For example, an embodiment was manufactured like that of FIG. 1, in which a memory cell having two-layer laminated encapsulation structure, which comprised a 5 nm layer of silicon nitride as a first layer, and 5 nm layer of silicon oxide as a second layer was compared with a memory cell having a three-layer laminated encapsulation structure, which comprised a 5 nm layer of silicon nitride as a first layer, a 5 nm layer of silicon oxide as a second layer, and 5 nm layer silicon nitride as a third layer. The comparison measured endurance cycling of the two-layer encapsulated memory cell and the three-layer encapsulated memory cell. It is found that after 1E7 (10 million) cycles, the structure having the two-layer laminated encapsulation was likely to fail (15 of 40 tested cells behaved as if they were shorted after 1E7 cycles). However, after 1E7 cycles, the structure having the three-layer laminated encapsulation, 39 of the 39 tested non-defective cells maintained their memory cell On/Off properties. Also, it is found that threshold drift during the endurance cycling was reduced. Thus, a laminated encapsulation structure for a phase change memory cell is provided having at least three layers with essentially no threshold degradation and with maintained memory threshold window for at least 1E7 cycles.

FIG. 7 is a schematic 3D cross point memory device, according to some embodiments of the disclosure. The cross point memory device includes an array of memory cells like that of FIG. 6, over a substrate. In preferred embodiments, all of the memory cells in the multiple layers of the device include laminated encapsulation structures, as represented by element 850. having at least three conformal layers which can be ALD deposited materials, in which the contacting layers are dissimilar. Also, in embodiments as described herein, the memory cell pillars have laminated encapsulation structure in which the first layer contacting the side walls of the pillar does not contain oxygen. In embodiments provided, the laminated encapsulation structure can comprise alternating layers of silicon nitride and silicon oxide in which the first layer is silicon nitride. Only one is illustrated to limit density of the Figure.

The substrate can include a semiconductor substrate, or a semiconductor substrate having circuits thereon. In some embodiments, the substrate is a back end of line (BEOL) substrate or a front end of line (FEOL) substrate. A plurality of word lines 830 and 831 are disposed on a bottom level. A plurality of bit lines 820, 821 are disposed in an intermediate level. A second plurality of word lines 810, 811 are disposed in an upper level in this portion of the array. Memory cells having the structure of FIG. 6 in this example, are disposed in the cross points of the bit lines and the word lines. Also, memory cells in the upper level share bit lines with memory cells in the lower level.

As in FIG. 6, each memory cell in the array includes an access device and a memory layer. In the illustrated embodiment, the memory cells are oriented such that the access device is below the memory layer. In other embodiments, the memory cells can be arranged so that the upper level has access devices above the memory layer, and the lower level has access devices below the memory layer.

The access device in this embodiment is an ovonic threshold switch including a first electrode 613, a chalcogenide-based selector layer 614, and a second electrode 615. The memory layer comprises a first barrier layer 615A on the second electrode 615, a layer of memory material 616 such as a phase change material on the first barrier layer 615A, a second barrier layer 617A on the layer of memory material 616, and a top electrode 617 on the second barrier layer.

A cross point array structure using laminated encapsulation can be manufacture in a number of ways. One first process scheme for each layer is to use lithography to define an etch pattern (litho) and to etch the pattern to form the plurality of first conductors 830, 831.Then inter-metal dielectric is deposited and chemical mechanical polishing CMP is used for planarization to expose the conductors 830, 831. The memory stack is deposited, and pillar cells are patterned by a litho and etch process. There is clean process after the pillar etch. Laminated ALD encapsulation is formed by a sequence of ALD procedures as described above, on the pillars and inter-layer dielectric will go after to fill the space. Inter-layer dielectric may not necessary when an air-gap allowed. Inter-layer dielectric CMP for planarization is used to expose the top barrier of pillar cells. A plurality of second conductors 820, 821 are deposited metal and patterned with a litho and etch process. The process can be repeated for multiple layers.

Another process scheme can include a self-aligned pillar cell. Materials of first conductors and memory stacks are deposited, and a first line litho exposure is made. A first line etch to pattern first conductors 830, 831 and memory stacks is used. There is clean process after first line etch. Laminated ALD encapsulation is formed by a sequence of ALD procedures as described above, on the first line pattern side wall. Inter-layer dielectric is deposited into the space and CMP planarization is used to expose the top barrier. Material of second conductors 820, 821 is deposited on top of the exposed barrier. A second line litho in another direction which is perpendicular to first direction is formed, and a second line etch is etch stopped on top of first conductors 830, 831. The pillar cell is the cross point of first and second line patterns and results from the second line etch. There is clean process after second line etch. Laminated ALD encapsulation is formed by a sequence of ALD procedures as described above, on the second line pattern side wall. Inter-layer dielectric is deposited into the space and CMP planarization to expose the top of second conductors 820, 821. The process can be repeated for multiple layers.

FIG. 8 illustrates a process which can be used for forming thin films of silicon nitride using ALD on the side walls of the memory pillar as described herein. According to the process the substrate having exposed side walls on the pillars is disposed in a reaction chamber. A carrier gas, such as an inert gas is flowed in the chamber having a temperature of about 250° C. During a first time window a precursor comprising Bis(t-butylamino)silane (BTBAS) is added to the flow, which forms a film on the substrate. During a second time window, a nitrogen carrying reactant, such as N2 dissociated plasma, is added to the flow during which formation of an atomic layer of silicon nitride having a thickness of about 0.16 Ångströms per cycle, occurs on the exposed substrate. After the second time window, the chamber is purged with pure carrier gas, and the cycle repeats. In an example system, the procedure can be repeated for about five hours to form 50 Å of silicon nitride on the side wall of the memory pillar as described herein.

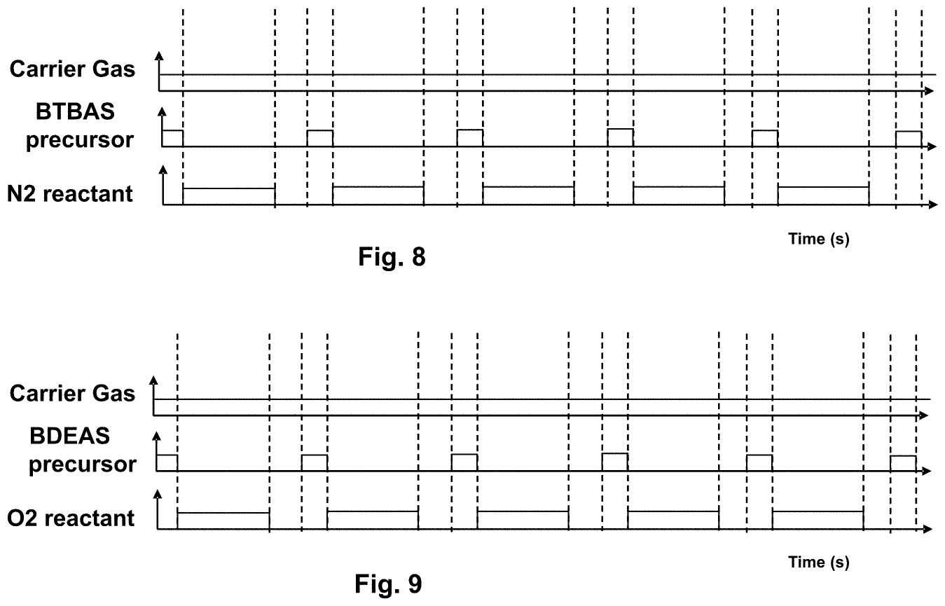

FIG. 9 illustrates a process which can be used for forming thin films of silicon oxide using ALD on a layer of silicon nitride, such as on the first layer of the encapsulation structure on the side walls of the memory pillar as described herein. According to the process the substrate is disposed in a reaction chamber. A carrier gas, such as an inert gas is flowed in the chamber having a temperature of about 250° C. During a first time window a precursor comprising Bis(diethylamino)silane (BDEAS) is added to the flow, which forms a film on the substrate. During a second time window, an oxygen carrying reactant, such as O2 plasma, is added to the flow during which formation of an atomic layer of silicon oxide having a thickness of about 1 Ångström per cycle, occurs on the exposed substrate. After the second time window the chamber is purged with pure carrier gas, and the cycle repeats. In an example system, the procedure can be repeated for about one hour to form 50 Å of silicon oxide on the side wall as described herein.

Other ALD chemistries can be utilized to deposit thin, conformal layers, selected for compatibility with the adjacent layers, and for avoidance of damage to the active materials of the memory cell pillar.

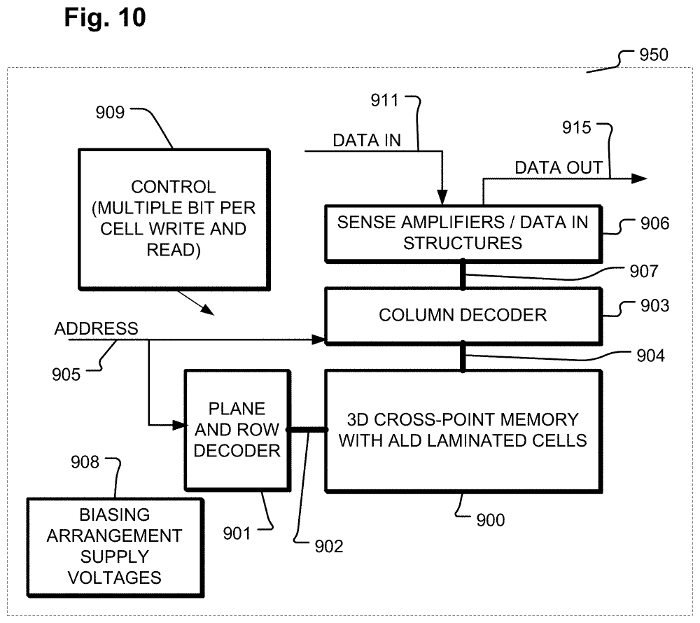

FIG. 10 shows an integrated circuit 950 including a 3D memory array 900 comprising memory cells including ovonic threshold switches in series with bodies of phase change material thermally confined by laminated encapsulation as described herein. A plane and row decoder 901 is coupled to, and in electrical communication with, a plurality of word lines 902, and arranged along rows in the memory array 900. A column decoder 903 is coupled to, and in electrical communication with, a plurality of bit lines 904 arranged along columns in the memory array 900 for reading data from, and writing data to, the memory cells in the 3D memory array 900. Addresses are supplied on bus 905 to the plane and row decoder 901 and to the column decoder 903. Sense amplifiers and other supporting circuitry such as pre-charge circuits and so on, along with data-in structures in block 906, are coupled to the column decoder 903 via the bus 907. Data is supplied via the data-in line 911 from input/output ports on the integrated circuit 950 or other data sources, to the data-in structures in block 906. Data is supplied via the data-out line 915 from the sense amplifiers in block 906 to input/output ports on the integrated circuit 950, or to other data destinations internal or external to the integrated circuit 950. Peripheral circuits on the integrated circuit are configured for reading and writing 3D cross-point memory 900. The peripheral circuitry can include a bias arrangement state machine in circuitry 909, controlling biasing arrangement supply voltages 908, and the sense circuitry and the data-in structures in block 906, for read and write operations. Also, the peripheral circuitry includes control circuitry 909 including logic such as state machines for read and write operations of the memory array 900. Incremental step pulse programming can be used, for example, to program the memory cells. Read logic can be included with multiple read thresholds applied to read more than one bit per cell. The control circuitry 909 can be implemented using special purpose logic, a general purpose processor or a combination thereof, configured to execute the read, write and erase operations.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A memory cell, comprising:
a first electrode and a second electrode;
a stack of materials having a side wall, the stack of materials in electrical series between the first and second electrodes, and including a layer of programmable resistance memory material; and
a laminated encapsulation structure surrounding the stack, the laminated encapsulation structure comprising a first conformal layer of a first material on the side wall of the stack, a second conformal layer of a second material different from the first material in contact with the first conformal layer, and a third conformal layer of a third material different from the second material in contact with the second conformal layer, the first material comprising a silicon nitride.

2. The memory cell of claim 1, including a spacer in the stack between the first conformal layer and the memory material.

3. The memory cell of claim 1, including an oxide layer in the stack between the first conformal layer and the memory material.

4. The memory cell of claim 1, wherein the second material comprises a silicon oxide and the third material comprises a silicon nitride.

5. The memory cell of claim 1, wherein the second material comprises an aluminum oxide and the third material comprises a silicon nitride.

6. The memory cell of claim 1, wherein the second material comprises a silicon oxynitride and the third material comprises a silicon nitride.

7. The memory cell of claim 1, wherein the first conformal layer has a thickness of more than 4 nm and less than 10 nm, the second conformal layer has a thickness of less than 5 nm and the third conformal layer has a thickness of less than 5 nm.

8. The memory cell of claim 1, including a dielectric layer in the stack between the first conformal layer and the memory material.

9. The memory cell of claim 1, wherein the first conformal layer is thicker than each of the second and third conformal layers.

10. The memory cell of claim 1, wherein the encapsulation structure includes a fourth conformal layer of a material different from the third material in contact with the third conformal layer, and a fifth conformal layer of a material different from the material of the fourth conformal layers and in contact with the fourth conformal layer.

11. The memory cell of claim 1, wherein the first, second and third materials are ALD deposited materials.

12. A memory cell, comprising:
a first electrode and a second electrode;
a pillar between the first and second electrodes, the pillar including a body of ovonic threshold switch material, one or more carbon-based intermediate layers, one or more metal layers and a body of phase change memory material in electrical series between the first and second electrodes; and
a laminated encapsulation structure surrounding the pillar, the laminated encapsulation structure comprising a first conformal layer of a first adjacent the phase change memory material, a second conformal layer of a second layer material different from the first layer material in contact with the first conformal layer; and
a third conformal layer of a third layer material different from the second layer material in contact with the second conformal layer.

13. The memory cell of claim 12, including a spacer between the first conformal layer and the phase change memory material.

14. The memory cell of claim 12, wherein the first layer material and the third layer material are a first dielectric material and the second layer material is a second material different from the first dielectric material.

15. The memory cell of claim 12, wherein the first layer material is a silicon nitride.

16. The memory cell of claim 12, wherein the first conformal layer is thicker than each of the second conformal layer and the third conformal layer.

17. The memory cell of claim 12, including a dielectric layer between the first conformal layer and the phase change memory material the dielectric layer comprising an oxide of an element of the phase change memory material.

18. The memory cell of claim 12, including a metal layer of the one or more metal layers is disposed between one of the one or more carbon-based intermediate layers and the body of phase change material layer.

19. The memory cell of claim 18, wherein the metal layer comprises tungsten.

20. A 3D memory device, comprising:
a memory structure including a layer of first conductors extending in a first direction alternating with a layer of second conductors extending in a second direction, and an array of memory cells disposed in cross-points between first conductors and second conductors, each memory cell in a corresponding cross-point in the array comprising a layer of ovonic threshold switch material, one or more carbon-based intermediate layers, one or more metal layers and a body of phase change memory material in electrical series; and
a laminated encapsulation structure, the laminated encapsulation structure comprising a first conformal layer of silicon nitride on a side wall of the memory cells, a second conformal layer of a second layer material of silicon oxide in contact with the first conformal layer, and a third conformal layer of silicon nitride in contact with the second conformal layer, the first conformal layer being thicker than each of the second and third conformal layers.
